(19) United States
(12) Patent Application Publication
(10) Pub. No.: US 2023/0324126 A1
(43) Pub. Date: Oct. 12, 2023

(54) SEALING MECHANISM AND TWO-PHASE WATERCOOLING HEAT DISSIPATION DEVICE

(71) Applicant: Wiwynn Corporation, New Taipei City (TW)

(72) Inventors: Pai-Chieh Huang, New Taipei City (TW); Chin-Han Chan, New Taipei City (TW); Hsien-Chieh Hsieh, New Taipei City (TW); Chin-Hao Hsu, New Taipei City (TW)

(73) Assignee: Wiwynn Corporation, New Taipei City (TW)

(21) Appl. No.: 17/888,510

(22) Filed: Aug. 16, 2022

Related U.S. Application Data
(60) Provisional application No. 63/328,722, filed on Apr. 7, 2022.

(30) Foreign Application Priority Data
Jun. 21, 2022 (TW) 111123015

(51) Int. Cl. F28D 7/16

(52) U.S. Cl. CPC F28D 7/16

(57) ABSTRACT

A sealing mechanism is used to seal a sink of a case via a cover of a two-phase water-cooling heat dissipation device. The sealing mechanism includes a driving module and a guiding module. The driving module is disposed on the cover. The guiding module is linked with the driving module and includes a first connection component, a second connection component and a third connection component. The first connection component is driven by the driving module and includes a first constraining structure used to engage with and disengage from a restraining component for constraint of the cover. The second connection component is crossed by the first connection component. The third connection component is rotatably disposed on the cover. An end of the third connection component is connected to the second connection component, and the other end of the third connection component is connected to the first connection component.

### CROSS REFERENCE TO RELATED APPLICATIONS

This application claims the benefit of U.S. Provisional Application No. 63/328,722, filed on Apr. 7, 2022. The content of the application is incorporated herein by reference.

### BACKGROUND OF THE INVENTION

### 1. Field of the Invention

The present invention relates to a sealing mechanism and a two-phase water-cooling heat dissipation device, and more particularly, to a sealing mechanism of evenly pressing the cover and effectively preventing structural deformation and a related two-phase water-cooling heat dissipation device.

### 2. Description of the Prior Art

A conventional immerged water-cooling apparatus can put a heat source inside a sink, and the sink is sealed by a cover for utilizing a water-cooling device of the immerged water-cooling apparatus to cool the heat source. Coolant in the water-cooling device is transformed from a liquid phase to a gaseous phase in response to increased temperature, and the cover of the water-cooling device applies stable pressure to the sink for preventing gaseous leakage. The cover has a first side and a second side opposite to each other. The first side is close to a pivot mechanism, and the cover is rotatably connected to the sink via the pivot mechanism. The second side is distant from the pivot mechanism. The second side or another side of the cover excluding the first side can be forced to rotate the cover. When the sink is sealed by the cover, the cover presses a section of an annular gasket adjacent to the pivot mechanism, and then presses another section of the annular gasket distant from the pivot mechanism in response to the second side of the cover contacting the sink. Thus, uneven pressure applied to the annular gasket results in uneven deformation. Some part of the annular gasket may be pushed out of an installation slot of the sink, or the cover may be deformed due to uneven pressure when the sink is sealed by the cover of the conventional immerged water-cooling apparatus, and therefore the conventional immerged water-cooling apparatus cannot provide preferred airtight efficiency.

### SUMMARY OF THE INVENTION

According to an embodiment of the invention, a sealing mechanism of sealing a sink via a cover includes a driving module and a guiding module. The driving module is disposed on the cover. The guiding module is linked with the driving module. The guiding module includes a first connection component, a second connection component and a third connection component. The first connection component is driven by the driving module and includes a first constraining structure. The first constraining structure is adapted to engage with or disengage from a restraining component so as to constrain a movement of the cover relative to the sink. The second connection component is intersected to the first connection component. The third connection component is rotatably disposed on the cover. An end of the third connection component is connected to the second connection component, and the other end of the third connection component is connected to the first connection component.

According to an embodiment of the invention, a two-phase water-cooling heat dissipation device includes two-phase water-cooling heat dissipation device, a cover and a sealing mechanism. The case includes a sink and at least one restraining component. A heat dissipation medium and a heat generation component are accommodated inside the sink, and the at least one restraining component is disposed around the sink. The cover is movably disposed on the case. The sealing mechanism of sealing the sink via the cover includes a driving module and a guiding module. The driving module is disposed on the cover. The guiding module is linked with the driving module. The guiding module includes a first connection component, a second connection component and a third connection component. The first connection component is driven by the driving module and includes a first constraining structure. The first constraining structure is adapted to engage with or disengage from a restraining component so as to constrain a movement of the cover relative to the sink. The second connection component is intersected to the first connection component. The third connection component is rotatably disposed on the cover. An end of the third connection component is connected to the second connection component, and the other end of the third connection component is connected to the first connection component.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are diagrams of a two-phase water-cooling heat dissipation device in different operation modes according to an embodiment the present application.

FIG. 3 and FIG. 4 are diagrams from top view of the sealing mechanism in different operation modes according to the embodiment the present application.

FIG. 5 is a diagram of a part of the sealing mechanism according to the embodiment the present application.

FIG. 6 is a diagram of another part of the sealing mechanism according to the embodiment the present application.

FIG. 7 is a diagram of the guiding module according to another embodiment of the present application.

### DETAILED DESCRIPTION

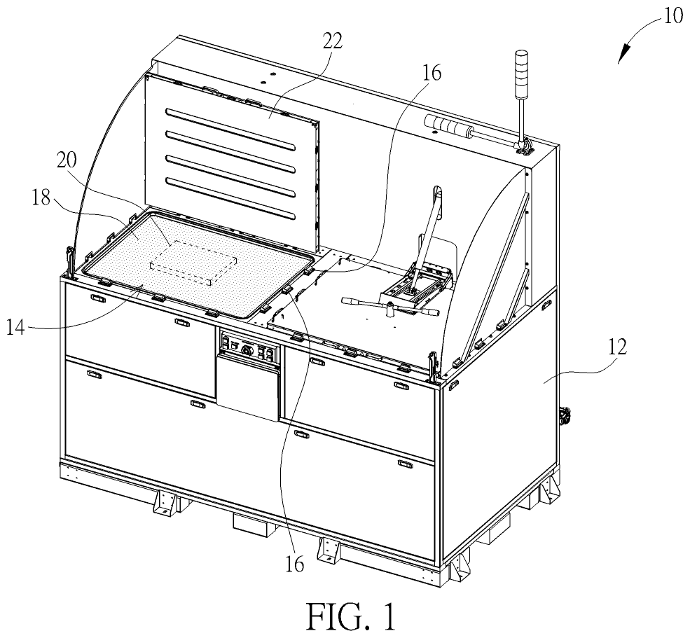

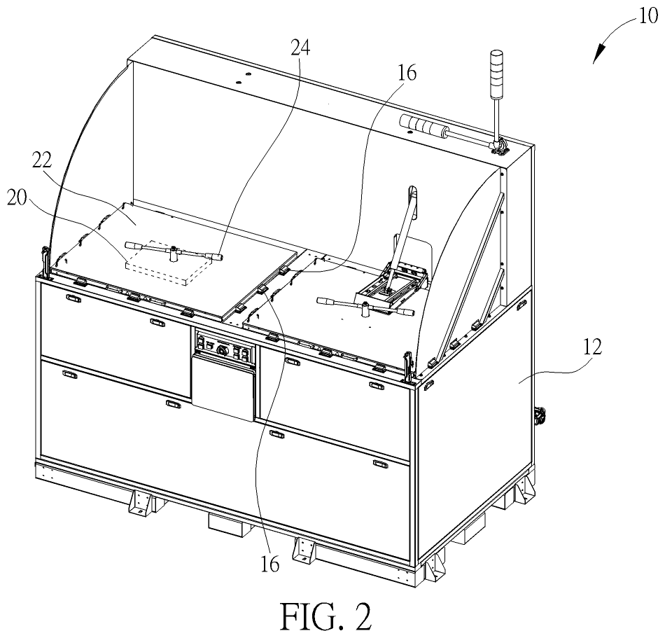

Please refer to FIG. 1 and FIG. 2. FIG. 1 and FIG. 2 are diagrams of a two-phase water-cooling heat dissipation device 10 in different operation modes according to an embodiment the present application. The two-phase water-cooling heat dissipation device 10 can dissipate heat generated by a heat source via phase change. The two-phase water-cooling heat dissipation device 10 can include a case 12. The case 12 can include a sink 14, a restraining component 16 and other structural components. The sink 14 can accommodate a heat dissipation medium 18, and a heat generation component 20 can be immersed in the heat dissipation medium 18. The restraining component 16 can be disposed around an opening of the sink 14. The foresaid structural components are not a design scope of the present application and can be omitted herein for simplicity.

The heat dissipation medium 18 can absorb the heat generated by the heat generation component 20, and can be transformed from a liquid phase to a gaseous phase. When the heat is released from the gaseous heat dissipation medium 18, the heat dissipation medium 18 can be transformed from the gaseous phase to the liquid phase. For preventing the gaseous heat dissipation medium 18 from leaking out the case 12, the two-phase water-cooling heat dissipation device 10 can further include a cover 22 and a sealing mechanism 24. The sealing mechanism 24 can be disposed on the cover 22. The cover 22 can be movably disposed on the case 12 and used to shelter an opening of the sink 14. The sealing mechanism 24 can be engaged with the restraining component 16 and used to press the cover 22. The opening of the sink 14 can be sealed by the cover 22 via the sealing mechanism 24, so as to effectively prevent the liquid heat dissipation medium 18 or the gaseous heat dissipation medium 18 from leakage.

It should be mentioned that the case 12 can be optionally provided with a slot (which is not marked in the figures) around the sink 14. A resilient component (which is not marked in the figures) can be disposed inside the slot. A size of the resilient component can be greater than a diameter of the slot. The sealing mechanism 24 can be operated to drive the cover 22 to vertically press the resilient component, and the resilient component can be deformed and tightly fill inside the slot. The resilient component cannot be over-deformed by impact of the gaseous heat dissipation medium 18. The heat dissipation medium 18 would hardly leak out from the sink 14 when an inner pressure of the case 12 different from ambient pressure.

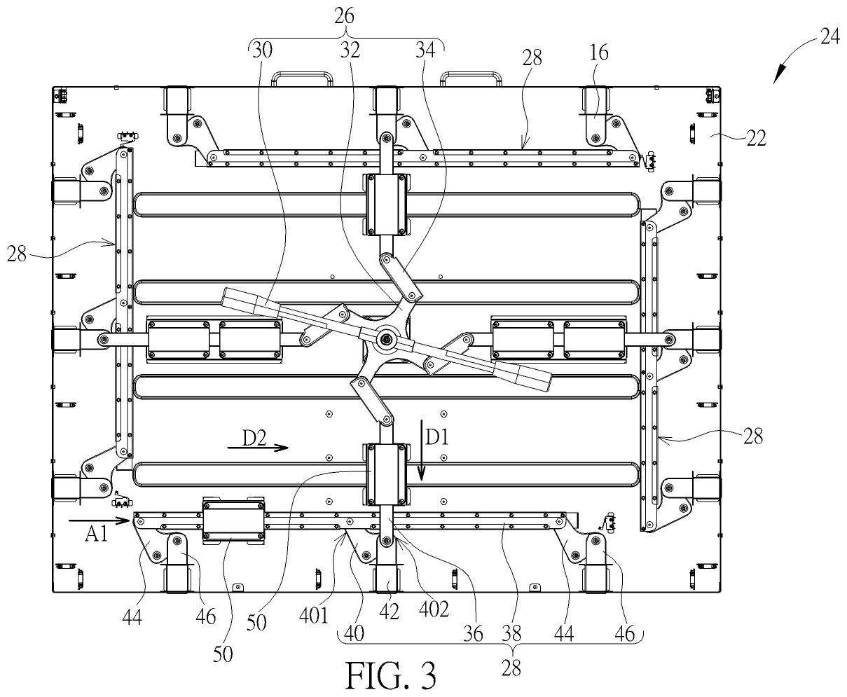

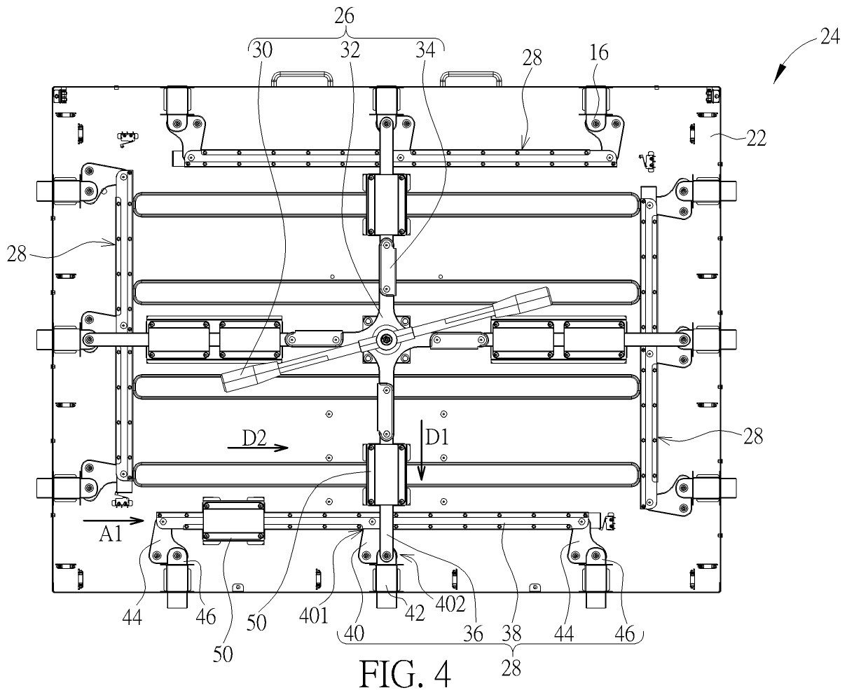

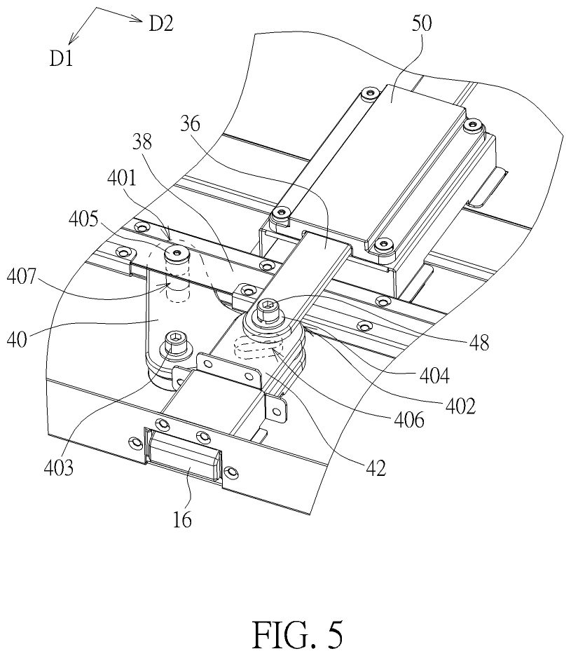

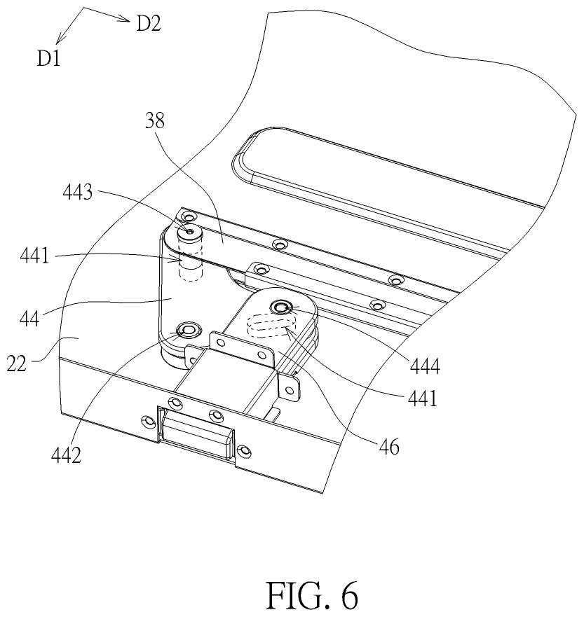

Please refer to FIG. 3 to FIG. 6. FIG. 3 and FIG. 4 are diagrams from top view of the sealing mechanism 24 in different operation modes according to the embodiment the present application. FIG. 5 is a diagram of a part of the sealing mechanism 24 according to the embodiment the present application. FIG. 6 is a diagram of another part of the sealing mechanism 24 according to the embodiment the present application. The sealing mechanism 24 can include a driving module 26 and a guiding module 28. A number of the guiding module 28 is not limited to the embodiment shown in the figures, and depends on a design demand. The driving module 26 can be disposed on the cover 22 and linked with the guiding module 28. The driving module 26 can be driven by a user to control motion of the guiding module 28, so as to utilize the sealing mechanism 24 to engage with the restraining component 16 and further to press the cover 22 for sealing. The driving module 26 can optionally include a handle 30, a first driving component 32 and a second driving component 34. The handle 30 can be a tool of controlling the sealing mechanism 24, and be disposed on the first driving component 32. The first driving component 32 can be a rotation plate disposed on the cover 22. Two opposite ends of the second driving component 34 are respectively connected to the first driving component 32 and the guiding module 28.

The driving module 26 of the embodiment can be manually operated by the user. The user can pull or push the handle 30 to rotate in a clockwise direction or in a counterclockwise direction, and the guiding module 28 can be drive to engage with or disengage from the restraining component 16 of the case 12.

In some embodiments, the driving module 26 may be replaced by an electric motor (which is not shown in the figures) and an operation interface, such as a touch panel, a mouse or a keyboard. The user can input a control command via the operation interface, and the electric motor can read the control command to drive the guiding module 28 to engage with or disengage from the restraining component 16 of the case 12. An actual application of the driving module 26 is not limited the foresaid two embodiments, and depends on the design demand.

The guiding module 28 can include a first connection component 36, a second connection component 38 and a third connection component 40. The first connection component 36 can be connected to the second driving component 34 of the driving module 26. The first connection component 36 can include a first constraining structure 42 used to engaged with or disengage from the restraining component 16 for constraining a movement of the cover 22 relative to the sink 14. The first constraining structure 42 and the restraining component 16 can respectively have corresponding inclined guiding surfaces, and the inclined guiding surfaces can be used to transform horizontal pushing force into vertical pressure. Structural parameters, such as an inclined angle and a surface dimension, of the inclined guiding surface can depend on the design demand. In the embodiment, the first constraining structure 42 and a main body of the first connection component 36 are two independent components; however, an actual application is not limited to the foresaid embodiment. For example, the first constraining structure 42 can be protruded from the main body of the first connection component 36, which means the first connection component 36 and the first constraining structure 42 are integrated monolithically.

The second connection component 38 can be intersected to the first connection component 36. In the embodiment, an included angle between the first connection component 36 and the second connection component 38 can be the same as or similar to ninety degrees. The foresaid included angle may be changed due to arrangement of connection components of the guiding module 28, and the detailed description of other possible embodiment is omitted herein for simplicity. The third connection component 40 can be rotatably disposed on the cover 22. The third connection component 40 can have a first end 401 and a second end 402 opposite to each other. The first end 401 can be connected to the second connection component 38. The second end 402 can be connected to the first connection component 36. In the embodiment, the second connection component 38 can be arranged along a boundary of the cover 22; for example, a major axis A1 of the second connection component 38 can be parallel to or substantially parallel to the boundary of the cover 22.

The guiding module 28 can further include a fourth connection component 44 and a second constraining structure 46. Two opposite ends of the fourth connection component 44 can be respectively pivoted to the second connection component 38 and the second constraining structure 46. The second constraining structure 46 can be engaged with or disengaged from the restraining component 16, so as to constrain a movement of the cover 22 relative to the sink 14. In the embodiment, a shape of the second constraining structure 46 can be similar to a shape of the first constraining structure 42. The second connection component 38 can be a rod having the major axis A1. The third connection component 40 and the fourth connection component 44 can be disposed on the second connection component 38 and spaced from each other along the major axis A1. For example, the third connection component 40 can be disposed on a middle portion of the second connection component 38, and the fourth connection component 44 can be disposed on a lateral portion of the second connection component 38. Position of the third connection component 40 and the fourth connection component 44 are not limited to the above-mentioned embodiment.

As shown in FIG. 5, the third connection component 40 can be a L-type structure with three pivoting parts. The three pivoting parts are not collinear, and can include one pivoting corner 403 and two pivoting terminals 404 and 405. The pivoting corner 403 of the third connection component 40 can be pivoted to the cover 22. The pivoting terminals 404 and 405 can be respectively pivoted to the first connection component 36 and the second connection component 38. A shape and a function of the fourth connection component 44 can be similar to a shape and a function of the third connection component 40. As shown in FIG. 6, a pivoting corner 442 of the fourth connection component 44 can be pivoted to the cover 22, and pivoting terminals 443 and 444 of the fourth connection component 44 can be respectively pivoted to the second connection component 38 and the second constraining structure 46.

Besides, a sliding hole 406 can be formed on the second end 402 of the third connection component 40. The first connection component 36 can be slidably connected to the third connection component 40 by inserting a pin 48 into the sliding hole 406, so that the first connection component 36 can be moved in a straight direction in response to rotation of the third connection component 40. A sliding hole 407 may be optionally formed on the first end 401 of the third connection component 40. The second connection component 38 can be slidably connected to the third connection component 40 by inserting the pin (which is not marked in the figures) into the sliding hole 407, and therefore the second connection component 38 can be moved in the straight direction in response to the rotation of the third connection component 40. As shown in FIG. 6, a sliding hole 441 may be optionally formed on one or all of two opposite ends (which are near to the pivoting terminals 443 and 444) of the fourth connection component 44. The second connection component 38 and the second constraining structure 46 can be slidably connected to the fourth connection component 44 by inserting the pin (which is not marked in the figures) into the sliding hole 441. The second connection component 38 and the second constraining structure 46 can be moved in the straight direction in response to rotation of the fourth connection component 44.

Moreover, the cover 22 can optionally include a guiding component 50. The guiding component 50 can be a hollow channel. The first connection component 36 can be movably disposed inside the guiding component 50, and a movement of the first connection component 36 in a first direction D1 can be constrained accordingly. The second connection component 38 can be movably disposed inside another guiding component 50, and a movement of the second connection component 38 in a second direction D2 can be constrained accordingly. A number and a position of the guiding component 50 can depend on numbers and positions of the first connection component 36 and the second connection component 38.

In the embodiment of the present application, the sealing mechanism 24 can have one driving module 26 and four guiding modules 28. The guiding modules 28 can be linked with the driving module 26, and respectively disposed on four sides of the cover 22. A number and a position of the guiding module 28 are not limited to the embodiment of the present application, and depend on the design demand. Each of the guiding modules 28 can have one first constraining structure 42 and two second constraining structures 46. A number of the restraining component 16 can correspond to a total number of the first constraining structure 42 and the second constraining structure 46.

In the foresaid embodiment, the first connection component 36, the second connection component 38, the third connection component 40 and the fourth connection component 44 of the guiding module 28 can be connected to set as linkage assembly. The guiding module 28 can be driven by the driving module 26 to rotate the third connection component 40 and the fourth connection component 44 disposed on the boundary of the cover 22, and the first constraining structure 42 and the second constraining structure 46 can be actuated to stick out the boundary of the cover 22 or move back to an original position for engaging with or disengaging from the restraining component 16. For example, when the driving module 26 is rotated in the counterclockwise direction, such as the embodiment shown in FIG. 3 to the embodiment shown in FIG. 4, the first connection component 36 can be pushed by the second driving component 34, and the first constraining structure 42 can be driven by the first connection component 36 to engage with the restraining component 16; when the first connection component 36 is shifted, the third connection component 40 can be driven to move the second connection component 38 and rotate the fourth connection component 44, so that the second constraining structure 46 and the first constraining structure 42 can be simultaneously engaged with the corresponding restraining components 16. When the driving module 26 is rotated in the clockwise direction, such as the embodiment shown in FIG. 4 to the embodiment shown in FIG. 3, the first connection component 36 can be pulled by the second driving component 34, and the third connection component 40 can be driven by the first connection component 36 to move the second connection component 38 and rotate the fourth connection component 44, so that the first constraining structure 42 and the second constraining structure 46 can be simultaneously disengaged from the corresponding restraining components 16.

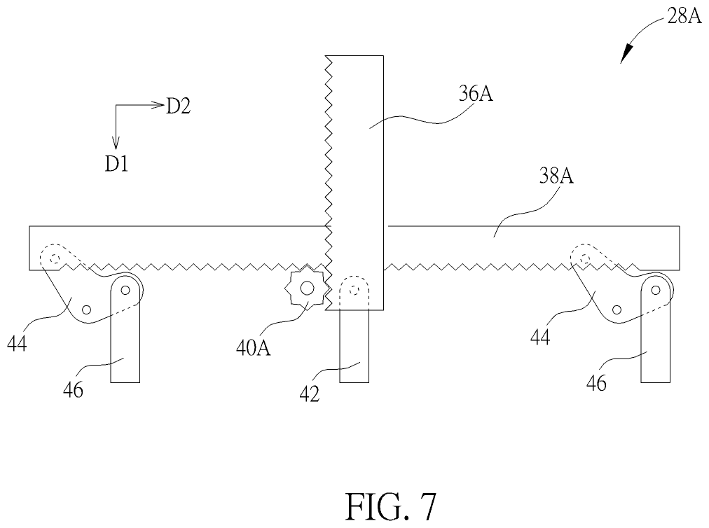

Please refer to FIG. 7. FIG. 7 is a diagram of the guiding module 28A according to another embodiment of the present application. In the embodiment, elements having the same numerals as ones of the foresaid embodiment have the same structures and functions, and the detailed description is omitted herein for simplicity. The first connection component 36A and the second connection component 38A of the guiding module 28A can respectively have a rack. The third connection component 40A can have a gear. The third connection component 40A (such as the gear) can be simultaneously engaged with the first connection component 36A and the second connection component 38A (such as the racks). When the first connection component 36A is shifted by the driving module 26, the first connection component 36A can directly move the first constraining structure 42 along the first direction D1, and further utilize the third connection component 40A to move the second connection component 38A along the second direction D2, so as to rotate the fourth connection component 44 and move the second constraining structure 46. The first constraining structure 42 and the second constraining structure 46 can be simultaneously disengaged from the corresponding restraining components 16.

In conclusion, the sealing mechanism and the two-phase water-cooling heat dissipation device of the present application can pull or push along the major axis of the first connection component, so that the first connection component made by light weight material can sustain a huge force to effectively prevent structural deformation. In addition, the guiding module of the sealing mechanism can utilize the first connection component to move the second connection component via rotation of the third connection component, and the second connection component can be pulled or pushed along its major axis, so that the second connection component made by the light weight material can sustain the huge force to prevent structural deformation. The second connection component can utilize the third connection component and the fourth connection component to simultaneously move the first constraining structure and the second constraining structure. The driving module of the sealing mechanism can drive the plural guiding modules at the same time, and each of the plural guiding modules can drive the plural constraining structures to simultaneously engage with or disengage from the restraining components, so as to ensure that the resilient component can be pressed by the cover in an even and vertical manner to tightly fill with the slot of the sink for preferred sealing efficiency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A sealing mechanism of sealing a sink via a cover, the sealing mechanism comprising:
a driving module disposed on the cover; and
a guiding module linked with the driving module, the guiding module comprising:
a first connection component driven by the driving module and comprising a first constraining structure, the first constraining structure being adapted to engage with or disengage from a restraining component so as to constrain a movement of the cover relative to the sink;
a second connection component intersected to the first connection component; and
a third connection component rotatably disposed on the cover, an end of the third connection component being connected to the second connection component, and the other end of the third connection component being connected to the first connection component.

2. The sealing mechanism of claim 1, wherein the guiding module further comprises a second constraining structure adapted to engage with or disengage from another restraining component, the guiding module further comprises a fourth connection component, two opposite ends of the fourth connection component are respectively pivoted to the second connection component and the second constraining structure.

3. The sealing mechanism of claim 2, wherein the second connection component comprise a major axis, the third connection component and the fourth connection component are arranged and spaced from each other along the major axis.

4. The sealing mechanism of claim 1, wherein the first connection component, the second connection component and the third connection component are connected with each other to be linkage assembly.

5. The sealing mechanism of claim 4, wherein the second connection component is arranged along a boundary of the cover.

6. The sealing mechanism of claim 1, wherein the first connection component and the second connection component respectively comprise a rack, and the third connection component comprises a gear engaged between the first connection component and the second connection component.

7. The sealing mechanism of claim 1, wherein a sliding hole is formed on the other end of the third connection component, and the first connection component is slidably connected to the third connection component by a pin arranged in the sliding hole.

8. The sealing mechanism of claim 1, wherein a sliding hole is formed on the end of the third connection component, and the second connection component is slidably connected to the third connection component by a pin arranged in the sliding hole.

9. The sealing mechanism of claim 2, wherein a sliding hole is formed on one of the two opposite ends of the fourth connection component, and one of the second connection component and the second constraining structure is slidably connected to the fourth connection component by a pin arranged in the sliding hole.

10. The sealing mechanism of claim 1, wherein the driving module comprises a handle, a first driving component and a second driving component, the handle is disposed on the first driving component, the first driving component is rotatably disposed on the cover, the second driving component is connected between the first driving component and the first connection component.

11. A two-phase water-cooling heat dissipation device comprising:
a case comprising a sink and at least one restraining component arranged around the sink, wherein the sink is configured to accommodate heat dissipation medium and a heat generation component;
a cover movably disposed on the case; and
a sealing mechanism comprising:
a driving module disposed on the cover; and
a guiding module linked with the driving module, the guiding module comprising:
a first connection component driven by the driving module and comprising a first constraining structure, the first constraining structure being adapted to engage with or disengage from the at least one restraining component so as to constrain a movement of the cover relative to the sink;
a second connection component intersected to the first connection component; and
a third connection component rotatably disposed on the cover, an end of the third connection component being connected to the second connection component, and the other end of the third connection component being connected to the first connection component.

12. The two-phase water-cooling heat dissipation device of claim 11, wherein the sealing mechanism further comprises a plurality of guiding modules linked with the driving module and respectively disposed on several sides of the cover.

13. The two-phase water-cooling heat dissipation device of claim 11, wherein the case comprises two restraining components, the guiding module further comprises a second constraining structure adapted to engage with or disengage from one of the two restraining components, the guiding module further comprises a fourth connection component, two opposite ends of the fourth connection component are respectively pivoted to the second connection component and the second constraining structure.

14. The two-phase water-cooling heat dissipation device of claim 13, wherein the second connection component comprise a major axis, the third connection component and the fourth connection component are arranged and spaced from each other along the major axis.

15. The two-phase water-cooling heat dissipation device of claim 11, wherein three pivoting parts of the third connection component are respectively pivoted to the cover, the second connection component and the first connection component, wherein the three pivoting parts are not collinear.

16. The two-phase water-cooling heat dissipation device of claim 11, wherein a sliding hole is formed on the other end of the third connection component, and the first connection component is slidably connected to the third connection component by a pin arranged in the sliding hole.

17. The two-phase water-cooling heat dissipation device of claim 11, wherein a sliding hole is formed on the end of the third connection component, and the second connection component is slidably connected to the third connection component by a pin arranged in the sliding hole.

18. The two-phase water-cooling heat dissipation device of claim 13, wherein a sliding hole is formed on one of the two opposite ends of the fourth connection component, and one of the second connection component and the second constraining structure is slidably connected to the fourth connection component by a pin arranged in the sliding hole.

19. The two-phase water-cooling heat dissipation device of claim 11, wherein the driving module comprises a handle, a first driving component and a second driving component, the handle is disposed on the first driving component, the first driving component is rotatably disposed on the cover, the second driving component is connected between the first driving component and the first connection component.

20. The two-phase water-cooling heat dissipation device of claim 11, wherein the cover comprises a guiding component, at least one of the first connection component and the second connection component is movably disposed inside the guiding component so as to constrain a moving direction of the first connection component or the second connection component.
